(19) United States
(12) Patent Application Publication
(10) Pub. No.: US 2004/0170925 A1
(43) Pub. Date: Sep. 2, 2004

(54) Positive imageable thick film compositions

(76) Inventors: David Herbert Roach, Hockessin, DE (US); Young H. Kim, Hockessin, DE (US); Lap-Tak Andrew Cheng, Newark, DE (US)

Correspondence Address: E I DU PONT DE NEMOURS AND COMPANY, LEGAL PATENT RECORDS CENTER, BARLEY MILL PLAZA 25/1128, 4417 LANCASTER PIKE, WILMINGTON, DE, 19805, US

(21) Appl. No.: 10/728,210

(22) Filed: Dec. 4, 2003

Related U.S. Application Data
(60) Provisional application No. 60/431,392, filed on Dec. 6, 2002.

(51) Int. Cl. G03F 7/004; G03F 7/039; G03F 7/32

(52) U.S. Cl. 430/281.1; 430/322; 430/330; 430/312

(57) ABSTRACT

This invention provides compositions that can be used as positive imageable photoresists. These compositions include positive imageable photopolymer systems and particulate materials. These compositions can be used in thick film and other processes to make films and patterned structures that are useful in producing electronic devices.

### FIELD OF THE INVENTION

This invention relates to positive imageable compositions useful in thick film, photoresist applications. In particular, this invention relates to compositions of positive imageable photopolymer systems and particulate materials. This invention also relates to processes for using such particulate-filled compositions for fabrication, as well as to films and other electronic devices made from such compositions.

### BACKGROUND OF THE INVENTION

Display screens are used in a wide variety of applications such as home and commercial televisions, laptop and desktop computers, indoor and outdoor advertising, and information presentations. Flat panel displays can be much thinner and lighter than the cathode ray tube monitors found on most televisions and desktop computers, but they are also difficult to produce in large format sizes. This is due in part to the current manufacturing processes, which involve the build-up of several layers of dielectric, conductive and emissive areas by thin film deposition, coating and/or photoimaging. Maintaining the required accurate registration of patterns, one on top of another, can be challenging.

It is also difficult to fabricate electronic devices for flat panel displays such as triodes with lateral dimensions less than 100 μm. If the printing methods lack resolution and/or registration accuracy, electrical shorting may occur between the gate and emitter layers. Since the features on each layer must be printed one layer at a time, repeated re-positioning of different screens tends to degrade overall registration fidelity in typical screen printing processes. In order to prevent shorting, the gate layer opening is often enlarged relative to the dielectric via, with the undesirable consequence that the effectiveness of the gate-switching field is degraded due to increased gate-to-emitter distance.

A photoimagable thick film approach can solve the aforementioned problems by reducing the number of screen changes and/or by allowing the use of a previously formed image as an in-situ mask for subsequently formed patterns. This approach is useful for forming an array of normal gate triodes, as well as for forming an array of inverted-gate triodes.

To take maximum advantage of a previously formed image as an in-situ mask, the photoresist used should be positive imageable. A positive imageable photoresist produces an exact image of the original because areas exposed to light undergo chemical changes that render the exposed portions of the photoresist soluble in suitable solvents, while unexposed areas remain insoluble. Several positive imageable photoresists are described in Photoreactive Polymers: The Science and Technology of Resists (A. Reiser), John Wiley & Sons, New York, 1988.

PCT/US01/19580 discloses the use of particulate-filled negative imageable photoresist compositions (such as Fodel® silver and dielectric paste compositions from DuPont) in a process for making cathode assemblies.

Although there is a wide variety of positive imageable photoresists known, these materials are typically applied as a thin film by spin coating, and particulates are considered a contaminant therein. There is no particulate-filled, positive imageable photoresist composition that is suitable for use in a thick film process for making electronic devices. Thus, there is a continuing need for commercially viable, particulate-filled, positive imageable photoresist compositions.

### SUMMARY OF THE INVENTION

One embodiment of this invention is a positive imageable, particulate-filled photoresist composition containing (a) at least one positive imageable photopolymer system, and (b) about 1 to about 70 vol % particulates.

The composition can be used to form a printable paste, a film (such as a thick film), an electron field emitting film, a field emission triode, a field emission display, a lighting device, or a vacuum electronic device.

Another embodiment of this invention is a process for creating images on a substrate by:

(a) depositing the positive imageable, particulate-filled photoresist composition of this invention as a film on a substrate;

(b) exposing the film imagewise to radiation to form exposed and unexposed portions thereof; and

(c) removing the exposed portions to form a developed image.

Another embodiment of this invention is a process for creating a multi-layer patterned structure by:

(a) depositing a first composition of this invention as a first film on a substrate;

(b) depositing a second composition of this invention, as a second film, onto the first film;

(c) exposing the first and second films imagewise to radiation to form exposed and unexposed portions;

(d) removing the exposed portions to form a developed image.

The developed image can be heated to form a patterned structure, which can take the form of an insulator, a conductor or a semi-conductor.

In yet another embodiment of this invention, multiple films prepared from the composition of this invention can be deposited, in conjunction with the process described above, simultaneously or sequentially.

This invention also provides a simplified process for producing electronic devices such as triodes, vacuum electronic devices, lighting devices and displays, and methods for making such devices.

The improved electronic devices of this invention are fabricated from the compositions of this invention, and are useful in: flat panel computer, television, and other types of displays; vacuum electronic devices; emission gate amplifiers; klystrons; and lighting devices. The compositions of matter and processes hereof are especially advantageous for producing large area electron field emitters for flat panel displays, i.e., for displays greater than 30 inches (76 cm) in length or width. The flat panel displays can be planar or curved.

### BRIEF DESCRIPTION OF THE DRAWINGS

FIG. 1 shows a normal gate triode in cross-section.

FIG. 2 shows a field emission display device in cross-section.

### DETAILED DESCRIPTION OF THE INVENTION

This invention provides a particulate-filled photoresist composition that is useful in manufacturing components for a wide variety of electronic devices. The compositions of this invention contain at least one positive imageable photopolymer system, and about 1 to about 70 percent particulates by volume (vol %). These compositions are frequently applied as a thick film, i.e., a film of about 5 microns or greater thickness.

Typically, a photopolymer system contains one or more radiation-curable or radiation-imageable polymers or resins, and one or more photo-active compounds. A positive imageable photopolymer system is a system that, when used as a photoresist, produces an exact image of the original because areas exposed to light undergo chemical changes that render the exposed portions of the photoresist soluble in suitable solvents, while unexposed areas remain insoluble. The use of a positive imageable photopolymer system as a photoresist is described in Photoreactive Polymers: The Science and Technology of Resists (A. Reiser), John Wiley & Sons, New York, 1988.

Examples of photopolymer systems useful herein include those in which novolacs are blended with a photoactive component such as a diazoketone (e.g., a diazonaphthoquinone). A second type of suitable positive imageable photopolymer system is made up of a polymer, such as a polyhydroxystyrene or polymethacrylic acid polymer, that has a pendant acid-labile carbonate or ester groups [e.g., t-Boc (t-butoxyoxycarbonyl)], that may be cleaved off from the polymer chain as acid is generated from a photo-acid generator (PAG) upon irradiation. Such systems are well-known and many are commercially available.

More particularly, suitable positive imageable photopolymer systems include those based on the addition of photo-active components, such as a diazoquinone or diazonaphthoquinone (DNQ), to phenolic resins. The phenolic resins are phenol-formaldehyde polycondensates, commonly known as a “novolac”. The preferred phenolic compounds are cresols or other alkylated phenols. Other photo-active diazo compounds that can be used in place of diazoquinone and diazonaphthaquinone, particularly at deep UV wavelengths, include diazo-Meldrum's acid, diazopyrazolidine dione, diazotetramic acid, diazopiperidine dione or 2-diazodimedones. The preferred molar ratio of polymer to photo-active component in such a system, particularly in the case of a novolac, is about 1 to 0.025 to about 1 to 0.5.

Novolac-based positive imageable photopolymer systems may function by the so-called “dissolution inhibitor mechanism”. The photo-active component (e.g., diazoquinone) is insoluble in the typical developers, such as a 0.5% NaOH solution, and reduces the dissolution rate of unexposed novolac to about 1-2 nm/sec. After exposure to light, the photo-active component is transformed into a compound (e.g., a carboxylic acid) that is soluble in the developer, rendering the exposed areas of resin more soluble as well.

Alternatively, a photo-active component can be incorporated into a photopolymer system by grafting it to a polymer or to a small molecule. A photo-active component suitable for grafting can be prepared, for example, by the base-catalyzed condensation of a diazonaphthoquinone sulfonyl chloride with a mono- or poly-hydroxy species to produce a sulfonate ester. The structure of the photo-labile portion of such a component, e.g. a diazonaphthoquinone group, and the structure of the photo-inert ballast can be readily and independently changed. Many variations of such photo developable materials are commercially available.

There are also a large number of positive imageable photopolymer systems based on the chemical amplification of acid generated by radiation. Since, for example, the quantum yield of the novolac/DNQ based system is relatively low, a chemically amplified system may be preferred when a high level of particulates is employed. The main components of a chemically amplified system are (a) a polymer that contains acid-labile pendant ester groups, and (b) a PAG. When light falls on a photoresist composition containing a PAG, the PAG generates an acid, which hydrolyses the ester group of the polymer and makes the exposed part of the resist soluble in aqueous base.

One such polymer for use in a chemically-amplified system is poly(t-butoxyoxycarbonylstyrene) (PTBOCST), or a copolymer thereof, in which segments have good compatibility with dispersed particles. Bonds are cleaved as a result of photolysis, and a small quantity of acid is formed in those areas exposed to radiation. During a later heating step, the acid catalyzes thermolysis of pendent t-butoxyoxycarbonyl groups, converting the nonpolar PTBOCST into the polar poly(hydroxystyrene) and gaseous products, while regenerating the initial acid. The exposed portion is developed with typical developers, such as a 0.5% NaOH solution.

Polymers and copolymers of either acrylic or methacrylic [“(meth)acrylic”] acid or (meth)acrylates have also been synthesized for use as a component in a positive imageable photopolymer system, and are useful in this invention. Suitable monomers for a (meth)acrylic acid or (meth)acrylate polymer or copolymer are those that contain acid-labile ester groups, which are cleaved off from the polymer chain as acid is generated upon irradiation by the presence in the system of a PAG.

Representative examples of pendent acid labile groups useful in a (meth)acrylic acid or (meth)acrylate polymer or copolymer in this invention may be described by the formulas I, II or III:

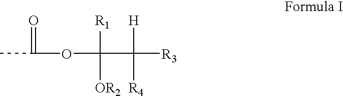

wherein R₁ is hydrogen or C₁-C₆ alkyl; R₂ is C₁-C₆ alkyl; and R₃ and R₄ independently are hydrogen or C₁-C₆ alkyl; and wherein R₁ and R₂, or R₁ and R₃, or R₂ and R₃ may be joined to form a 5-, 6-, or 7-membered ring.

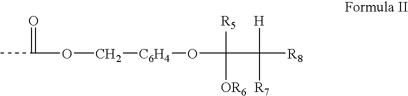

wherein n is 0-4; R₅ is hydrogen or C₁-C₆ alkyl; R₆ is C₁-C₆ alkyl; and R₇ and R₈ independently are hydrogen or C₁-C₆ alkyl; and wherein R₅ and R₆, or R₅ and R₇, or R₆ and R₇ may be joined to form a 5-, 6-, or 7-membered ring.

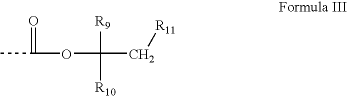

where R₉ is hydrogen or lower alkyl; R₁₀ is lower alkyl; and R₁₁ is hydrogen or lower alkyl; and wherein a lower alkyl group includes alkyl groups having 1 to 6 linear or 3 to 6 cyclic carbon atoms.

Examples of these and other acid labile monomeric components that are useful in the preparation of a positive imageable photopolymer system include:

1-ethoxyethyl (meth)acrylate,

1-butoxyethyl (meth)acrylate,

1-ethoxy-1-propyl (meth)acrylate,

tetrahydropyranyl (meth)acrylate,

tetrahydropyranyl p-vinylbenzoate,

1-ethoxy-1-propyl p-vinylbenzoate,

4-(2-tetrahydropyranyloxy)benzyl (meth)acrylate,

4-(1-butoxyethoxy)benzyl (meth)acrylate,

t-butyl (meth)acrylate,

neopentyl (meth)acrylate,

1-bicyclo{2,2,2}octyl (meth)acrylate and their derivatives,

1-bicyclo{2,2,1}heptyl (meth)acrylate and their derivatives,

1-bicyclo{2,1,1}hexyl (meth)acrylate and their derivatives,

1-bicyclo{1,1,1}pentyl (meth)acrylate and their derivatives, and

1-adamantyl (meth)acrylate and their derivatives.

Block copolymers that are useful in the preparation of a positive imageable photopolymer system can be prepared by one of several well-known methods, such as: living, or controlled, polymerization; anionic or group transfer polymerization; and atom transfer polymerization. The terms and techniques regarding living, controlled, and atom transfer polymerization are discussed in “Controlled/Living Radical Polymerization”, edited by K. Matyjaszewski, Oxford University Press.

Random copolymers that are useful in the preparation of a positive imageable photopolymer system can be obtained by solution polymerization using typical free radical initiators, such as organic peroxide and azo initiators. Discussion of these polymerization methods can be found in “Polymer Chemistry”, Fifth Edition by C. E. Carraher Jr, Marcel Dekker Inc., New York, N.Y. (see Chapters 7,8 and 9); or “Polymers” by S. L. Rosen in The Kirk-Othmer Encyclopedia of Chemical Technology, Fourth Edition, John Wiley and Sons Inc., New York (see volume 19, pp 899-901).

Comonomers containing additional functional groups can also be incorporated into a positive imageable photopolymer system as used herein. The preferred comonomers are selected to improve the mechanical properties of the final copolymer, and/or to improve the compatibility of the matrix polymer with the particles. Examples of such comonomers are acrylic monomers and hydroxyl styrene monomers containing alkylethyleneoxide units.

The preferred molecular weight of a positive imageable photopolymer as used in the photopolymer system hereof is about 1,000 to about 300,000.

A photoinitiator may be used herein as the photo-active compound. As defined by Reiser (vide supra), photoinitiators are molecules or molecular systems that are capable of forming radicals upon irradiation. Typical positive working photoinitiators are PAGs. Examples of such compounds are described by J. V. Crivello, “The Chemistry of Photoacid Generating Compounds”, Polymeric Materials Science and Engineering preprint, Vol. 61, American Chemical Society Meeting (Miami, Fla., Sep. 11-15, 1989), pp 62-66, and references therein.

Suitable particulates for incorporation into the composition hereof should have limited or no reactivity with the photopolymer system. Suitable particulates include particles, powders, and nanostructured materials such as nanotubes. Suitable sources of powders, particles, and nanostructured materials include metals (such as transition metals), metalloids, metal/metalloids, and their respective alloys; solder powders; oxides; nitrides; carbides and nanostructured carbons. Mixtures of any and all such particles, powders and nanostructured materials can also be used. More specifically, such powders or particles can be derived from glass; metal oxides such as aluminum oxides, tin oxides, silicon oxides, and titanium oxides; nitrides such as aluminum nitride and silicon nitride; carbon such as carbon powders and nanostructured carbons such as carbon-containing nanotubes; metals such as the transition elements; metalloids such as zinc, thallium, germanium, cadmium, indium, tin, antimony, lead, and bismuth; or other inorganics such as solder powders and alloys of the above metals and/or metalloids; and mixtures of any two or more of any of the foregoing.

For applications in which a composition of this invention is applied as a thick film composition and is a precursor to a conductive or insulating inorganic structure or layer, inorganic powder or particles should be used together with a high-temperature binder, e.g., a low-melting glass. Suitable binders should have a softening point below about 1000° C., preferably below about 600° C. A glass frit that softens sufficiently at the firing temperature to adhere to a substrate and to the particles or powders is typically used. Lead or bismuth glass frits can be used, as well as other glasses with low softening points, such as calcium or zinc borosilicates. Within this class of glasses, the specific composition is generally not critical. Variations in the composition of the binder can be used to adjust the viscosity and the final thickness of the printed material.

For applications in which a structure or layer formed from a composition of this invention is inorganic and conductive, the preferred inorganic particles or powders to be used are those derived from transition metals, metalloids, metal alloys, or mixtures thereof. Most preferred are highly conductive metals such as Al, Cu, Ag, Au, Pt and Pd.

For many electronic device applications, the particle size of the particulates (such as powders, particles or nanostructured materials) is also important because particle size can determine the uniformity and thickness of the sintered structure or layer, formed from a composition of this invention. Preferably, the particulates are less than 100 microns, more preferably less than 10 microns, and most preferably less than 3 microns, in the longest dimension.

For those applications in which the composition is applied as a thick film, and is a precursor to an electron emitter or an electron emitting layer, it is preferred that the particles have an aspect ratio (i.e., ratio of longest dimension to shortest dimension) of at least about 10. The composition from which an electron field emitter is fabricated can contain, in addition to the electron emitting substance, such particulates as glass frits, metallic powder or metallic paint, or a mixture thereof, for assistance in attachment of the electron emitting composition to a substrate. Preferably, the electron emitting particles are carbon nanotubes or Bxcy Nz nanotubes (as described, for example, in U.S. Pat. No. 6,057,637).

In addition to the powders and/or particles, the positive imageable photopolymer, and/or a photo-active component, the compositions of this invention can contain other additives, such as solvents, dispersants and viscosity aids. These additives serve to suspend and disperse the particulate constituents, giving pastes the proper rheology for typical patterning processes such as screen printing. Examples of resins that can be used to obtain a suspension and/or a dispersion include cellulosic resins such as ethyl cellulose and alkyd resins of various molecular weights. Butyl carbitol, butyl carbitol acetate, dibutyl carbitol, dibutyl phthalate and terpineol are examples of useful solvents. These and other solvents are formulated to obtain the desired viscosity and volatility requirements in the composition.

A surfactant can be used to improve the dispersion of the particles. Organic acids, such oleic and stearic acids, and organic phosphates, such as lecithin or Gafac® phosphates, are typical surfactants.

In the particulate-filled photoresist composition of this invention, particulates comprise about 1 to about 70 vol % of the composition, preferably about 20 to about 70 vol %, and more preferably about 50 to about 70 vol % of the composition, with the balance being a positive imageable photopolymer system and any additives that may be desirable.

The particulate-filled photoresist composition of this invention is typically prepared by mixing particulates with a photopolymer system and, in most embodiments, a photo-active component, by any of several techniques. At low solids loading, even simple stirring in a suitable solvent can be used. At high solids loadings, high-shear methods such as roll-milling may be necessary.

The composition of this invention in the form of a paste can be screen printed to form a film. Another preferred method of preparing a photosensitive layer is by covering a substrate with the composition of this invention preformed as a film, for example as a green tape. Such film can be prepared on another flexible film, such as a Mylar® film, by solvent casting.

Alternatively, a solution containing a composition of this invention can be cast into a film of desired thickness using a roller coater or a doctor's knife on a flexible plastic film, and the resulting photo-active layer can be overlaid on the substrate. Low boiling solvents, such as 2-butanone, tetrahydrofuran, and the like can be used in such a process.

Various processes can be used to pattern the composition of this invention onto a substrate. A preferred method is to screen print the composition, and then dry it to an insoluble film. Another preferred method is to overlay a film formed from the composition with a backing onto a substrate. The film can be photo developed into the desired pattern, and one can then optionally remove the backing and wash out the positively developed area with a developing agent. The remaining portion of the film is then fired to make the desired layer. For some applications, e.g., those requiring finer resolution, the preferred process may involve pre- and post-baking of the films prior to firing the patterned paste.

The composition can be screen printed using well-known screen printing techniques, e.g., by using a 165-400-mesh stainless steel screen. A paste can be deposited as a continuous film or in the form of a desired pattern. The deposited pastes can be further defined or patterned by UV imaging and development with a base. When the substrate is glass, the deposited, and optionally patterned, material is then fired at a temperature of about 350° C. to about 650° C., preferably at about 450° C. to about 550° C. Higher firing temperatures can be used with substrates that can endure such temperatures. The organic constituents in the paste are effectively volatilized at 350-550° C., leaving a layer of the inorganic particles and/or powders, which may be partially sintered. For lower firing systems, a methacrylate or acrylate polymer matrix is preferred.

The substrate can be any material to which the composition of this invention will adhere. Silicon, glass, metal or a refractory material such as alumina can serve as the substrate. For display applications, the preferable substrate is glass, and soda lime glass is especially preferred.

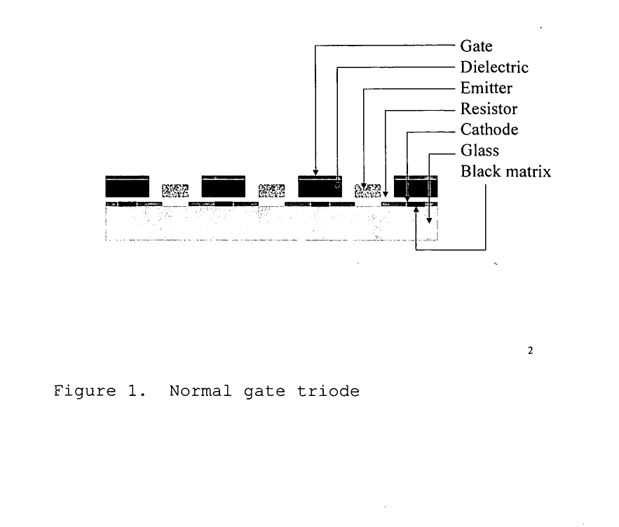

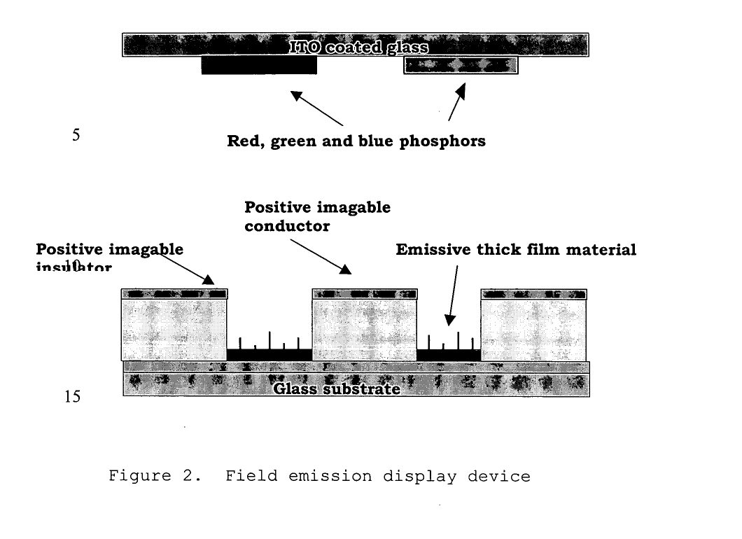

The patterned and/or layered inorganic structures thus provided can be used in the cathodes of electronic devices such as triodes and field emission display devices. As seen in FIG. 1, a normal gate triode may contain a gate, a dielectric, an emitter, a resistor, a cathode, a glass substrate, and a black matrix (a layer of dark or black glass that provides a contrast-enhancing outline around the pixels). As seen in FIG. 2, a field emission display device may contain (a) a cathode using an electron field emitter (such as an emissive thick film material), (b) an optically transparent electrically conductive film [such as an ITO (indium tin oxide) coated glass substrate] serving as an anode and spaced apart from the cathode, (c) a phosphor layer (including, for example, red, green and blue phosphors) capable of emitting light upon bombardment by electrons emitted by the electron field emitter and positioned on or adjacent to the anode, and between the anode and the cathode, (d) one or more gate electrodes (such as a layer of a positive imageable conductor) disposed between the phosphor layer and the cathode, (e) an insulator such as a layer of a positive imageable insulator, and (f) a substrate such a glass substrate. The use of a composition of this invention to fabricate the cathode, including the insulator, and gate structures is readily adapted to cathodes of large size display panels.

Use of the compositions of this invention enables the fabrication of completely screen-printed triodes, such as electron field emitting triodes. Typically, a uniform layer of the composition is screen printed on a substrate with controlled thickness. The layer is baked in low heat to dry. A photo-mask or photo-tool with the desired pattern is placed near, or in contact with, the film layer and exposed to ultra-violet (UV) radiation. Alternatively, a pattern can be directly applied to the substrate to eliminate registration problems. Or a combination of masks (contact masks and those directly deposited on the substrate) can be used. The film layer is then developed in weak aqueous sodium hydroxide.

By use of a composition of this invention, imaging can be carried out in multi-layers to eliminate or reduce alignment problems. This is advantageous in the fabrication of the normal gate triode, since the silver gate and dielectric layers can be imaged together to achieve perfect alignment between the gate and dielectric openings. In the fabrication of the inverted gate triode, the emitter, silver cathode, and dielectric layers can be imaged together to achieve perfect capping of the dielectric ribs, while avoiding the formation of shorts.

Use of a composition of this invention for fabricating an electron field emitter also enables the fabrication of a lighting device. Such a device comprises (a) a cathode using an electron field emitter that has been fabricated according to the invention, and (b) an optically transparent electrically conductive film serving as an anode and spaced apart from the cathode, and (c) a phosphor layer capable of emitting light upon bombardment by electrons emitted by the electron field emitter and positioned on or adjacent to the anode and between the anode and the cathode. The cathode typically comprises an electron field emitter in the form of a square, rectangle, circle, ellipse or any other desirable shape with the electron field emitter uniformly distributed within the shape, or the electron field emitter may be patterned. Screen printing is a convenient method for forming the electron field emitter, however, other patterning techniques can be used, such as spin coating, ink jet printing, stenciling or contact printing.

The compositions of this invention may also be used to make a vacuum electronic device.

In the fabrication of devices such as described above, it may be advantageous to employ a process for creating images on a substrate by depositing a composition of this invention as a film (such as a thick film) on a substrate; exposing the film imagewise to radiation to form exposed and unexposed portions thereof; and removing the exposed portions to form a developed image. The developed image may be heated to form a first patterned structure, and the patterned structure may be an insulator, a conductor, or a semi-conductor. If desired, a second film may be deposited onto the first patterned structure. If so, the second film may be exposed imagewise to radiation to form exposed and unexposed portions thereof; the exposed portions may be removed to form a second developed image; and the second developed image may be heated to form a second patterned structure. The first and second patterned structures may have the same size and shape.

Another useful approach to fabricating devices such as described above may be to employ a process for creating a multi-layer patterned structure by depositing a first composition of this invention as a first film (such as a thick film) on a substrate; depositing a second composition of this invention, as a second film, onto the first film; exposing the first and second films imagewise to radiation to form exposed and unexposed portions; and removing the exposed portions to form a developed image.

The developed image may be heated to form a patterned structure, and, if so, the patterned structure may be and insulator, a conductor or a semi-conductor.

Further, a third composition of this invention may be deposited, as a third film, onto the patterned structure.

Deposition in the above described processes may be performed by screen printing, spin coating, ink jet printing, contact printing or stenciling.

In this invention, radiation for photo activation or initiation that may be used includes radiation in the UV, visible and IR portions of the spectrum.

The advantages of this invention are demonstrated by examples, as described below. The embodiments of the invention on which the examples are based are illustrative only, and do not limit the scope of the invention.

### EXAMPLES

### Example 1

This example demonstrates positively imaged features of an electrically insulating material fabricated from a composition of, and by the process of, this invention.

The positively imagable insulator paste was prepared by mixing three components: a low softening bismuth borate frit; a liquid positive photoresist, Injectorall PC 197 (obtained from Injectorall Electronics, Inc., Bohemia, New York); and an ethylcellulose binder.

To form an insulating layer, 20 wt % resist was added to 3 wt % of ethylcellulose binder and 67 wt % bismuth borate frit. The combination was mixed in a glass plate muller for 75 rotations to form the insulator paste. A 2 cm² square pattern was then screen printed onto the pre-fired silvered glass substrate using a 200 mesh screen and the sample was subsequently dried at 125° C. for 10 minutes. After drying, the thick film composite forms an adherent coating on the substrate. The dried sample was then photo-patterned by using a photo tool containing 20 and 50 micrometer UV transparent holes. An UV dose of 1000 mJ was used for exposure. The exposed sample was developed in 0.5% NaOH aqueous solution for 2 minutes to wash out the exposed area of the sample. The developed sample was then rinsed thoroughly in water and allowed to dry. After drying, the substrates were fired at 515° C. with a residence time at peak temperature of 10 minutes. After firing, the material does not conduct on the maximum range of ohmmeter.

### Example 2

This example demonstrates the formation of positively imaged features in an electrically conductive material from a composition of, and by the process of, this invention.

The positively imagable conductor paste was prepared by mixing four components: an agglomerated dextrose reduced silver powder, with a BET surface area of 2.5 m²/g; a low softening bismuth borate frit; a positive photoresist, Injectorall PC 197; and an ethylcellulose binder.

To form a conducting layer, 19.9 wt % resist was added to 69.9 wt % silver powder, 9.9 wt % bismuth borate frit and 0.3 wt % ethylcellulose binder. The combination was mixed in a glass plate muller for 75 rotations to form the conductor paste. A 2 cm² square pattern was then screen printed onto the pre-fired silvered glass substrate using a 200 mesh screen and the sample was subsequently dried at 125° C. for 10 minutes. After drying the thick film composite forms an adherent coating on the substrate. The dried sample was then photo-patterned by using a photo tool containing 50 micrometer UV transparent holes. An UV dose of 1000 mJ was used for exposure. The exposed sample was developed in 0.5% NaOH aqueous solution for 2 minutes to wash out the exposed area of the sample. The developed sample was then rinsed thoroughly in water and allowed to dry. After drying the substrates were fired at 515° C. with a residence time at peak temperature of 10 minutes. A good conductor was obtained after firing as determined by an ohmmeter reading a direct short across the sample.

### Example 3

This example demonstrates the formation of positively imaged features in an electrically conductive material from a composition of, and by the process of, this invention.

The positively imagable conductor paste was prepared by mixing three components: an agglomerated dextrose-reduced silver powder, with a BET surface area of 2.5 m²/g; a positive photoresist, Clariant AZ 4620 (available from Clariant Corporation, AZ Electronic Materials, Somerville, N.J.); and an organic solvent.

To form a conducting layer, 22 wt % resist was added to 72 wt % silver powder and 6 wt % texanol solvent. The combination was roll-milled to form a paste. A layer of the material was applied to the substrate by spin coating at 3500 rpm for 1 minute, and the sample was subsequently dried at 100° C. for 10 minutes. After drying, the thick film composite forms an adherent coating on the substrate. The dried sample was then photo-patterned by using a photo tool containing 20 micrometer UV transparent holes. An UV dose of 500 mJ was used for exposure. The exposed sample was developed with Clariant AZ 421K (available from Clariant Corporation, AZ Electronic Materials, Somerville, N.J.) for 2.5 minutes to wash out the exposed area of the sample. The developed sample was then rinsed thoroughly in water and allowed to dry. After drying, the substrates were heated to 200° C. with a residence time at peak temperature of 3 minutes. A good conductor was obtained after firing, as determined by an ohmmeter reading a direct short across the sample. Higher temperature firing up to 525° C. also resulted in a direct short across the sample indicating very low resistance.

### Example 4

Poly(ethoxytriethylene glycol methacrylate-b-t-butyl methacrylate), (1.5 g, D.P. 37/100, Mn 28,600), TPS-109 photo acid generator, (0.5 g, Midori Kagaku Company Limited, Tokyo, Japan), and Quanticure ITX, (0.002 g, Sigma-Aldrich Chemical Co., Milwaukee, Wis.), were dissolved to a clear solution in 4 ml 2-butanone. To this was added 3.0 g of bismuth borate frit powder. A 2 mil film was formed using a doctor blade, the solution was cast on a Mylar® film and allowed to air dry for 10 minutes. The film was then dried for 30 minutes in a 100° C. convection oven.

A film square was placed in a plexiglass sample holder and backed by KAPTON® film (E.I. Dupont de Nemours and Company, Wilmington, Del.). A 50 micron photomask grid was placed over the top of the film and held in place by a large glass disk. An UV dose of 2000 mJ/cm2 was used for exposure. The exposed film was then heated to 120° C. for 3 minutes on a hot plate.

The film was then washed for 30 seconds with a 0.5% solution of sodium carbonate, followed by a 20 second rinse with distilled water. The film was dried with a stream of N₂. Examination of the developed film under a microscope showed that the exposed parts of the film had been removed.

### Example 5

A copolymer of poly(ethoxytriethylene glycol acrylate-random-t-butyl methacrylate), (0.72 grams, mole ratio of 70:30 of the monomers, Mn=10,400), 0.13 grams of DP=5 homopolymer of t-butyl methacrylate, 0.34 grams Cyracure® UVI-6976 50% solution (Dow Chemical), 0.99 mg Quanticure ITX (Aldrich), 0.99 mg of 2,3-diazabicyclo[3.2.2]non-2-ene, 1,4,4-trimethyl-, 2,3-dioxide (TAOBN) (Hampford Research, Inc., Stratford, Connecticut) and 1.0 g of bismuth borate frit powder were mixed in 1.98 g of PGMEA. Using a 2 mil thick template, the slurry mixture solution was cast on a glass plate and allowed to air dry for 10 minutes. The film was then dried for 2 min on a 70° C. hot plate. The film was exposed with approximately 1.5 J/cm2 broad band UV light using a 20 micron photomask, then heat-treated on a hot plate at 120° C. for 2 min. The imaged part was developed by spraying with a 0.5% sodium carbonate solution for 45 sec, to give a clear, hole-shaped pattern.

### Example 6

A copolymer of poly(ethoxytriethylene glycol acrylate-random-t-butyl methacrylate) (0.48 grams, mole ratio of 70:30 of the monomers, Mn=10,400), 0.08 grams of DP=5 homopolymer of t-butyl methacrylate, 0.22 grams Cyracure® UVI-6976 50% solution (Dow Chemical), 0.66 mg Quanticure ITX (Aldrich), 0.66 mg of 2,3-diazabicyclo[3.2.2]non-2-ene, 1,4,4-trimethyl-, 2,3-dioxide (TAOBN) (Hampford Research, Inc., Stratford, Connecticut), and 1.0 g of bismuth borate frit powder were mixed in 1.31 g of PGMEA. Using a 2 mil thick template, the slurry mixture solution was cast on a glass plate and allowed to air-dry for 10 min. The film was then dried for 2 min at 70° C. hot plate. The film was exposed with approximate 1.5 J/cm2 broad band UV light using a 20 micron photomask, then heat treated on a hot plate at 120° C. for 2 min. The imaged part was developed by spraying with a 0.5% sodium carbonate solution for 45 sec, to give clear, hole-shaped pattern.

This imaged film was heat-treated on a belt furnace heated to 525° C. in air for 20 mins. All polymer was burned at this temperature, and left sintered glass material on the glass plate.

What is claimed is:

1. A positive imageable, particulate-filled photoresist composition comprising (a) at least one positive imageable photopolymer system, and (b) about 1 to about 70 vol % particulates.

2. The composition of claim 1 wherein the particulates are selected from the group consisting of glass, oxides, carbides, nitrides, metals, metal alloys, metalloids, metalloid alloys, metal/metalloid alloys, carbon and mixtures thereof.

3. The composition of claim 2 wherein the oxides are selected from the group consisting of aluminum oxides, silicon oxides, tin oxides and mixtures thereof.

4. The composition of claim 1 wherein the particulates are selected from the group consisting of transition metals and their alloys.

5. The composition of claim 4 wherein the transition metals are selected from the group consisting of Al, Cu, Ag, Au, Pt, and Pd.

6. The composition of claim 1 wherein the particulates are selected from the group consisting of zinc, thallium, germanium, cadmium, indium, tin, antimony, lead, bismuth, and their alloys.

7. The composition of claim 1 wherein the particulates are selected from the group consisting of metal/metalloid alloys.

8. The composition of claim 2 wherein the carbon is in the form of carbon nanotubes.

9. The composition of claim 1 wherein the photopolymer system is selected from the group consisting of novolac-diazonaphthoquinone resins.

10. The composition of claim 1 wherein the photopolymer system is selected from the group of resins consisting of (meth)acrylate polymers and copolymers, wherein the resins contain pendant groups described by Formula I: 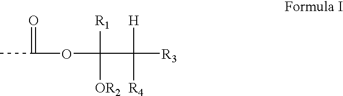
wherein R₁ is hydrogen or C₁-C₆ alkyl; R₂ is C₁-C₆ alkyl; and R₃ and R₄ independently are hydrogen or C₁-C₆ alkyl; and wherein R₁ and R₂, or R₁ and R₃, or R₂ and R₃ may be joined to form a 5-, 6-, or 7-membered ring.

11. The composition of claim 1 wherein the photopolymer system is selected from the group of resins consisting of (meth)acrylate polymers and copolymers, wherein the resins contain pendant groups described by Formula II: 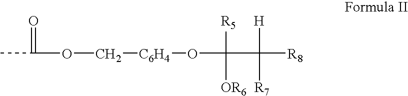
wherein n is 0-4; R₅ is hydrogen or C₁-C₆ alkyl; R₆ is C₁-C₆ alkyl; and R₇ and R₈ independently are hydrogen or C₁-C₆ alkyl; and wherein R₅ and R₆, or R₅ and R₇, or R₆ and R₇ may be joined to form a 5-, 6-, or 7-membered ring.

12. The composition of claim 1 wherein the photopolymer system is selected from the group of resins consisting of (meth)acrylate polymers and copolymers, wherein the resins contain pendant groups described by Formula III: 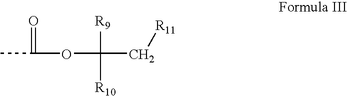
wherein R₉ is hydrogen or lower alkyl; R₁₀ is lower alkyl; and R₁₁ is hydrogen or lower alkyl; and wherein a lower alkyl group includes alkyl groups having 1 to 6 linear or 3 to 6 cyclic carbon atoms.

13. The composition of claim 1, wherein the photopolymer system comprises acid labile monomeric components selected from:
tetrahydropyranyl methacrylate (or acrylate);
tetrahydropyranyl p-vinylbenzoate;
1-ethoxy-l-propyl p-vinylbenzoate;
4-(2-tetrahydropyranyloxy)benzyl methacrylate (or acrylate);
4-(1-butoxyethoxy)benzyl methacrylate (or acrylate);
t-butyl methacrylate (or acrylate);
neopentyl methacrylate (or acrylate);
1-bicyclo{2,2,2}octyl methacrylate (or acrylate) and their derivatives;
1-bicyclo{2,2,1}heptyl methacrylate (or acrylate) and their derivatives;
1-bicyclo{2,1,1}hexyl methacrylate (or acrylate) and their derivatives;
1-bicyclo{1,1,1}pentyl methacrylate (or acrylate) and theirderivatives; and
1-adamantyl methacrylate (or acrylate) and their derivatives.

14. The composition of claim 1 further comprising additives selected from the group consisting of solvents and viscosity aids.

15. The composition of claim 1 wherein the particulates comprise about 20 to about 70 vol % of the composition.

16. The composition of claim 1 wherein the particulates are less than 100 microns in their longest dimension.

17. The composition of claim 1 wherein the particulates are less than 10 microns in their longest dimension.

18. The composition of claim 1 in the form of a printable paste.

19. The composition of claim 1 in the form of a film.

20. An electron field emitting film comprising the composition of claim 1.

21. A field emission triode comprising the film of claim 20.

22. A field emission display comprising the film of claim 20.

23. A lighting device comprising the film of claim 20.

24. A vacuum electronic device comprising the film of claim 20.

25. A process for creating images on a substrate comprising:
(a) depositing the composition of claim 1 as a film on a substrate;
(b) exposing the film imagewise to radiation to form exposed and unexposed portions thereof; and
(c) removing the exposed portions to form a developed image.

26. The process of claim 25 further comprising heating the developed image to form a first patterned structure.

27. The process of claim 26 wherein forming a patterned structure comprises forming an insulator.

28. The process of claim 26 wherein forming a patterned structure comprises forming a conductor.

29. The process of claim 26 wherein forming a patterned structure comprises forming a semi-conductor.

30. The process of claim 25 wherein the deposited film is a thick film.

31. A process according to claim 26 further comprising depositing a composition of claim 1, as a second film, onto the first patterned structure.

32. The process of claim 31 further comprising:
(a) exposing the second film imagewise to radiation to form exposed and unexposed portions thereof; and
(b) removing the exposed portions to form a second developed image; and
(c) heating the second developed image to form a second patterned structure;
wherein the first and second patterned structures have the same size and shape.

33. A process for creating a multi-layer patterned structure comprising:
(a) depositing a first composition of claim 1 as a first film on a substrate;
(b) depositing a second composition of claim 1, as a second film, onto the first film;
(c) exposing the first and second films imagewise to radiation to form exposed and unexposed portions;
(d) removing the exposed portions to form a developed image.

34. The process of claim 33 further comprising heating the developed image to form a patterned structure.

35. The process of claim 34 wherein forming a patterned structure comprises forming an insulator.

36. The process of claim 34 wherein forming a patterned structure comprises forming a conductor.

37. The process of claim 34 wherein forming a patterned structure comprises forming a semi-conductor.

38. The process of claim 33 wherein the deposited film is a thick film.

39. A process according to claim 34 further comprising depositing a third composition of claim 1, as a third film, onto the patterned structure.

40. A process according to claim 25 or 33 wherein the deposition comprises screen printing, spin coating, ink jet printing, contact printing or stenciling.
